(19) United States
(12) Patent Application Publication
(10) Pub. No.: US 2026/0330110 A1
(43) Pub. Date: Oct. 22, 2026

(54) DESIGN SUPPORT APPARATUS, DESIGN SUPPORT METHOD, COMPUTER PROGRAM, AND COMPUTER-READABLE MEDIUM

(71) Applicant: Kabushiki Kaisha Zuken, Kanagawa (JP)

(72) Inventors: Kazuma Oi, Kanagawa (JP); Shinji Takahashi, Kanagawa (JP); Kensuke Yoshijima, Kanagawa (JP); Shigeru Hayashi, Kanagawa (JP)

(21) Appl. No.: 19/547,930

(22) Filed: Feb. 24, 2026

Related U.S. Application Data
(63) Continuation of application No. PCT/JP2025/015218, filed on Apr. 18, 2025.

(51) Int. Cl. G06F 30/31; G06F 30/33; G06F 30/392

(52) U.S. Cl. CPC G06F 30/31; G06F 30/33; G06F 30/392

(57) ABSTRACT

A design support apparatus that supports layout design of an electronic circuit, includes a designation unit configured to designate a first point and a second point on a wiring path displayed on a display screen in response to an instruction from a user, a calculation unit configured to calculate an electric characteristic value between the first point and the second point on the wiring path, and a display control unit configured to display, on the display screen, the electric characteristic value calculated by the calculation unit.

### CROSS-REFERENCE TO RELATED APPLICATION(S)

This application is a continuation of International Patent Application No. PCT/JP2025/015218 filed on Apr. 18, 2025, the entire disclosures of which are incorporated herein by reference.

### TECHNICAL FIELD

The present invention relates to a design support apparatus, a design support method, a computer program, and a computer-readable medium.

### BACKGROUND ART

PTL 1 described a voltage drop calculation apparatus including a clearance hole extraction unit that extracts a power supply wiring pattern, a clearance hole formed on the power supply wiring pattern, and its position, a power supply wiring width calculation unit that calculates an effective wiring width on the power supply wiring pattern in the extracted clearance hole portion, and a voltage drop calculation unit that calculates a voltage drop in the power supply wiring portion based on the calculated effective wiring width.

### CITATION LIST

### Patent Literature

PTL 1: Japanese Patent Laid-Open No. 2011-133990

### SUMMARY OF INVENTION

When designing the layout pattern of a circuit, there may be a demand to know the resistance value between arbitrary two points. For example, when laying out a plurality of conductive paths forming a bus, it may be desired to compare the wiring resistance values of the respective conductive paths. Alternatively, when connecting two parts by a conductive path having a wiring resistance value within a certain target resistance value, it may be desired to know the wiring resistance value of the already laid conductive path. However, no tool has conventionally been provided that allows a user to designate arbitrary two points on a conductive path and know the resistance value between those two points.

The present invention provides a tool that allows a user to designate arbitrary two points on a conductive path and know the resistance value between those two points.

A first aspect of the present invention is directed to a design support apparatus that supports layout design of an electronic circuit, and the design support apparatus comprises: a designation unit configured to designate a first point and a second point on a wiring path displayed on a display screen in response to an instruction from a user; a calculation unit configured to calculate an electric characteristic value between the first point and the second point on the wiring path; and a display control unit configured to display, on the display screen, the electric characteristic value calculated by the calculation unit.

A second aspect of the present invention is directed to a design support method for supporting layout design of an electronic circuit, and the design support method comprises: a designation step of designating a first point and a second point on a wiring path displayed on a display screen in response to an instruction from a user; a calculation step of calculating an electric characteristic value between the first point and the second point on the wiring path; and a display control step of displaying, on the display screen, the electric characteristic value calculated in the calculation step.

A third aspect of the present invention is directed to a design support apparatus that supports layout design of an electronic circuit, and the design support apparatus comprises: at least one processer, and at least one memory, and in the at least one memory, a program is stored. The program causes the at least one processor to operate: as a designation unit configured to designate a first point and a second point on a wiring path displayed on a display screen in response to an instruction from a user; a calculation unit configured to calculate an electric characteristic value between the first point and the second point on the wiring path; and a display control unit configured to display, on the display screen, the electric characteristic value calculated by the calculation unit.

A fourth aspect of the present invention is directed to a computer program that causes a computer to operate as a design support apparatus that supports layout design of an electronic circuit, and the design support apparatus comprises: a designation unit configured to designate a first point and a second point on a wiring path displayed on a display screen in response to an instruction from a user; a calculation unit configured to calculate an electric characteristic value between the first point and the second point on the wiring path; and a display control unit configured to display, on the display screen, the electric characteristic value calculated by the calculation unit.

A fifth aspect of the present invention is directed to a non-transitory computer readable medium storing a program that causes a computer to operate as a design support apparatus that supports layout design of an electronic circuit, and the design support apparatus comprises: a designation unit configured to designate a first point and a second point on a wiring path displayed on a display screen in response to an instruction from a user; a calculation unit configured to calculate an electric characteristic value between the first point and the second point on the wiring path; and a display control unit configured to display, on the display screen, the electric characteristic value calculated by the calculation unit.

### BRIEF DESCRIPTION OF DRAWINGS

FIG. 1 is a view showing the arrangement of a design support apparatus according to an embodiment;

FIG. 2 is a view exemplifying the display image of the display screen of the display of the design support apparatus according to the embodiment;

FIG. 3 is a view exemplifying the display image of the display screen of the display of the design support apparatus according to the embodiment;

FIG. 4 is a view exemplifying the display image of the display screen of the display of the design support apparatus according to the embodiment;

FIG. 5 is a view exemplifying the display image of the display screen of the display of the design support apparatus according to the embodiment;

FIG. 6 is a view exemplifying the display image of the display screen of the display of the design support apparatus according to the embodiment;

FIG. 7 is a view exemplifying the display image of the display screen of the display of the design support apparatus according to the embodiment;

FIG. 8 is a view exemplifying the display image of the display screen of the display of the design support apparatus according to the embodiment;

FIG. 9 is a view exemplifying the display image of the display screen of the display of the design support apparatus according to the embodiment;

FIG. 10 is a view exemplifying the display image of the display screen of the display of the design support apparatus according to the embodiment;

FIG. 11 is a view exemplifying the display image of the display screen of the display of the design support apparatus according to the embodiment;

FIG. 12 is a view exemplifying the display image of the display screen of the display of the design support apparatus according to the embodiment;

FIG. 13 is a flowchart exemplifying the operation of the design support apparatus according to the embodiment;

FIG. 14 is a flowchart exemplifying the operation of the design support apparatus according to the embodiment; and

FIG. 15 is a flowchart exemplifying the operation of the design support apparatus according to the embodiment.

### DESCRIPTION OF EMBODIMENTS

Hereinafter, embodiments will be described in detail with reference to the attached drawings. Note, the following embodiments are not intended to limit the scope of the claimed invention, and limitation is not made to an invention that requires a combination of all features described in the embodiments. Two or more of the multiple features described in the embodiments may be combined as appropriate. Furthermore, the same reference numerals are given to the same or similar configurations, and redundant description thereof is omitted.

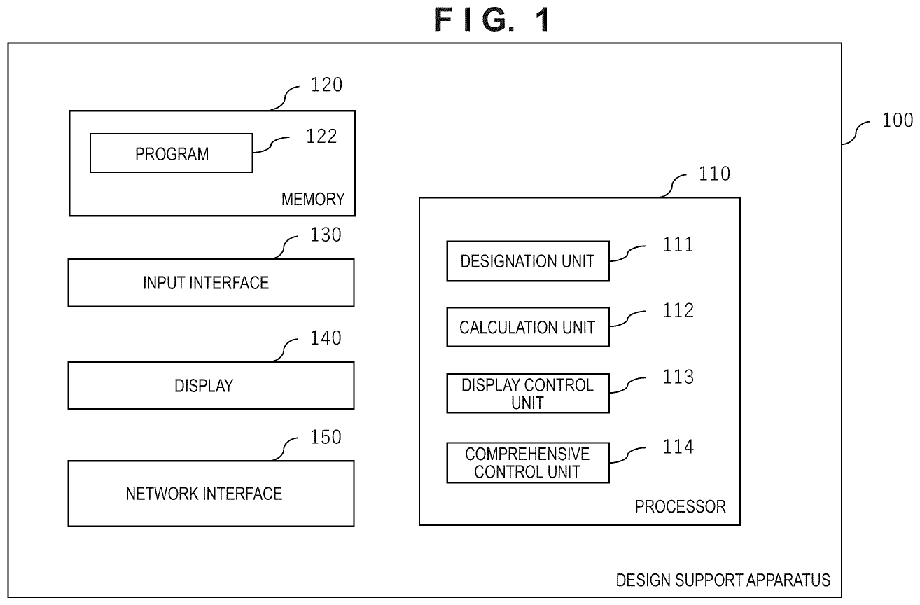

FIG. 1 shows the arrangement of a design support apparatus 100 according to an embodiment. The design support apparatus 100 can be implemented by, for example, installing a program in a computer. The design support apparatus 100 can be configured to support the layout design of an electronic circuit. The design support apparatus 100 can include, for example, a processor 110, a memory 120, an input interface 130, a display 140, and a communication network interface 150. The processor 110 includes a CPU and the like, and operates based on a program 122 stored in a memory 120, thereby being capable of implementing a function required of the design support apparatus 100. The program 122 can be non-temporarily stored in the memory 120. The program 122 may be non-temporarily stored in a computer readable medium and provided to the computer. The program 122 may be provided to the computer via a telecommunication network. The processor 110 operates based on the program 122, thereby being capable of constituting, for example, a designation unit 111, a calculation unit 112, a display control unit 113, and a comprehensive control unit 114. The input interface 130 can include, for example, a keyboard, a mouse, a touch panel, a microphone, or the like.

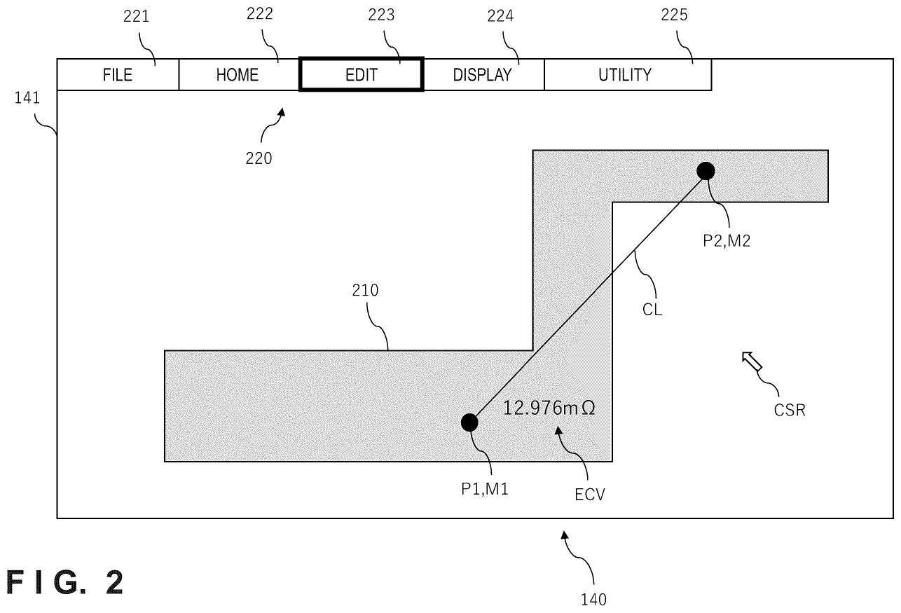

FIG. 2 schematically shows the display image of a display screen 141 of the display 140. The designation unit 111 can designate a first point P1 and a second point P2 on a wiring path 210 displayed on the display screen 141 of the display 140 in response to a user instruction given via the input interface 130. The calculation unit 112 can calculate an electric characteristic value ECV between the first point P1 and the second point P2 on the wiring path 210. The electric characteristic value ECV can be, for example, a resistance value, a parasitic capacitance value, a parasitic inductance value, or the like. The display control unit 113 can display, on the display screen 141 of the display 140, the electric characteristic value ECV calculated by the calculation unit 112. The display control unit 113 can display, on the display screen 141, a first mark M1 indicating the first point P1 and a second mark M2 indicating the second point P2 so as to overlap the wiring path 210. The display control unit 113 can display, on the display screen 141, a line CL connecting the first mark M1 and the second mark M2. The line CL makes it easy for the user to visually recognize the first mark M1 (or the first point P1) and the second mark M2 (or the second point P2).

The calculation unit 112 may be configured to calculate or re-calculate the electric characteristic value ECV between the first point P1 and the second point P2 in response to a trigger. In accordance with the calculation or re-calculation, the display control unit 113 can control display of the display screen 141 so as to update the electric characteristic value ECV displayed on the display screen 141. The trigger can include an edit operation of the wiring path 210 by the user. In a case where a plurality of wiring paths are displayed on the display screen 141, the trigger can be an edit operation of the wiring path 210 on which the first point P1 and the second point P2 are designated among the plurality of wiring paths. The trigger may be periodically given based on counting by a timer or the like. The trigger may be given by the user inputting information to the input interface 130.

The display control unit 113 may control display of the display screen 141 so as to delete the first mark M1 and the second mark M2, which are displayed on the display screen 141, in accordance with a user instruction given via the input interface 130. The comprehensive control unit 114 can control the designation unit 111, the calculation unit 112, and the display control unit 113.

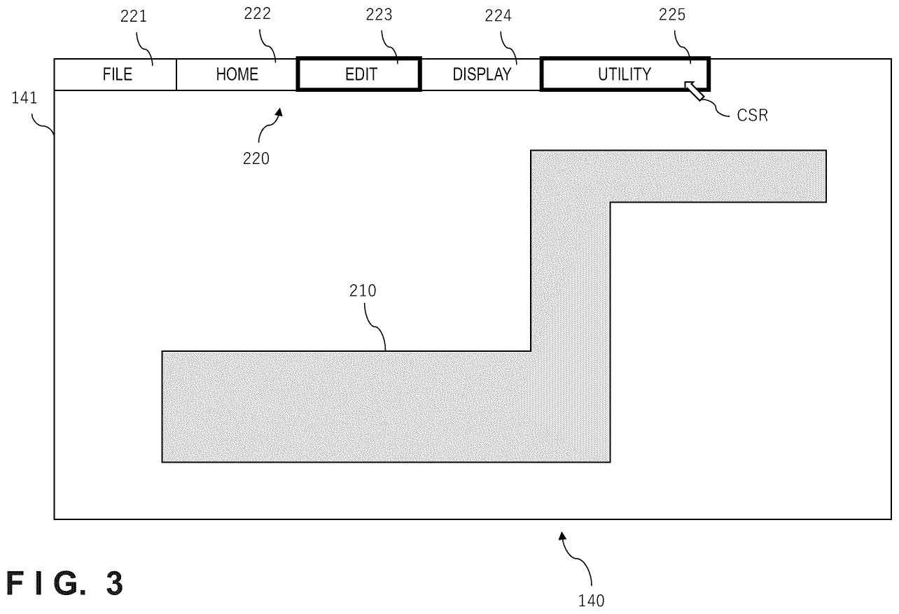

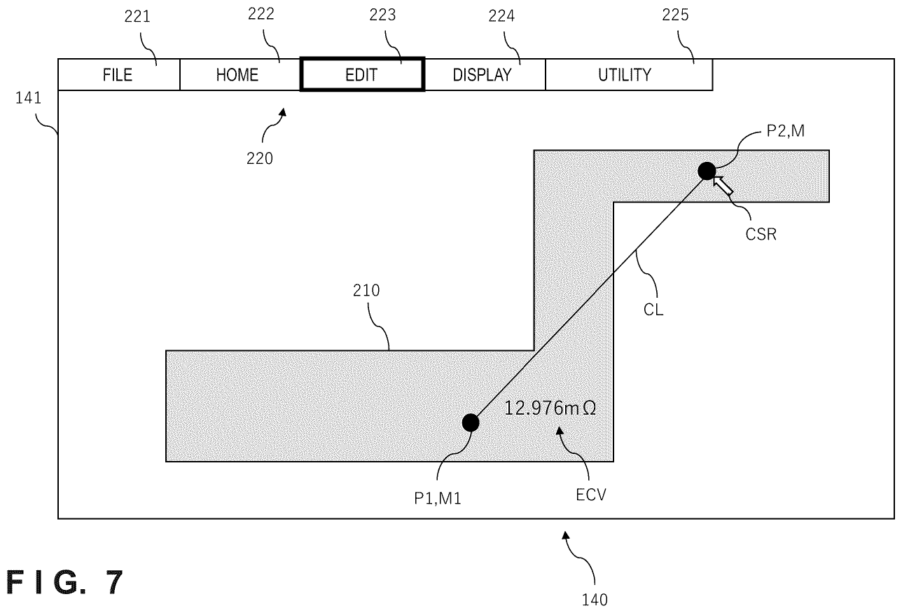

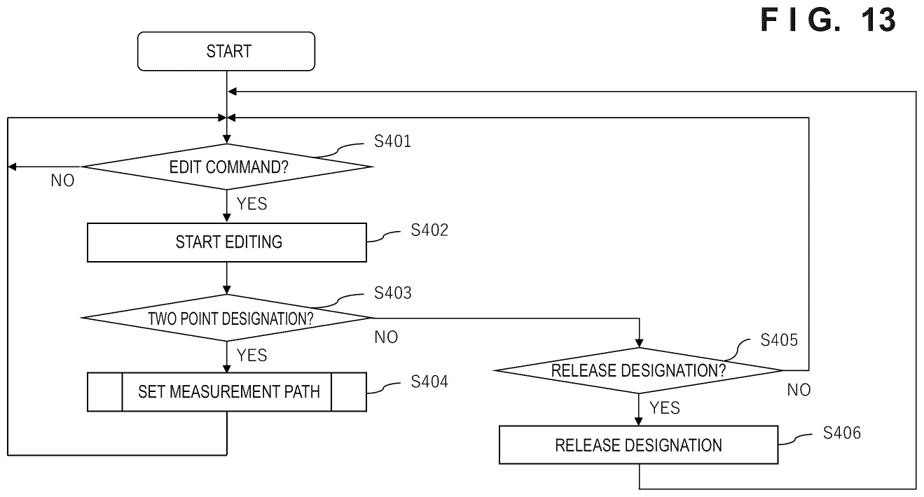

FIGS. 3 to 12 are views each exemplifying the display screen 141 of the display 140. FIGS. 13 to 15 are flowcharts each exemplifying the operation of the design support apparatus 100. The operation of the design support apparatus 100 will be described below with reference to these drawings. A menu 220 including a plurality of buttons can be displayed on the display screen 141 constantly or in accordance with a user instruction. The menu 220 can include, for example, a file menu button 221 for the user to instruct display of a file menu, a home button 222 for the user to instruct display of a home menu, an edit menu button 223 for the user to instruct display of an edit menu, a display menu button 224 for the user to instruct display of a display menu, a utility menu button 225 for the user to instruct display of a utility menu, and the like. The display screen 141 can include the display of a cursor CSR and the display of all or part (for example, the wiring path 210) of the layout of the electronic circuit design being edited.

In step S401, the comprehensive control unit 114 determines whether the user presses the edit menu button 223, as exemplified in FIG. 3, and further instructs execution of an edit command by operating the edit menu (not shown). If it is determined that the user instructs execution of an edit command, the comprehensive control unit 114 performs editing corresponding to the edit command or starts editing corresponding to the edit command in step S402. If editing is started in step S402, in response to a subsequent operation given by the user, further editing can be performed or execution of the edit command can be terminated.

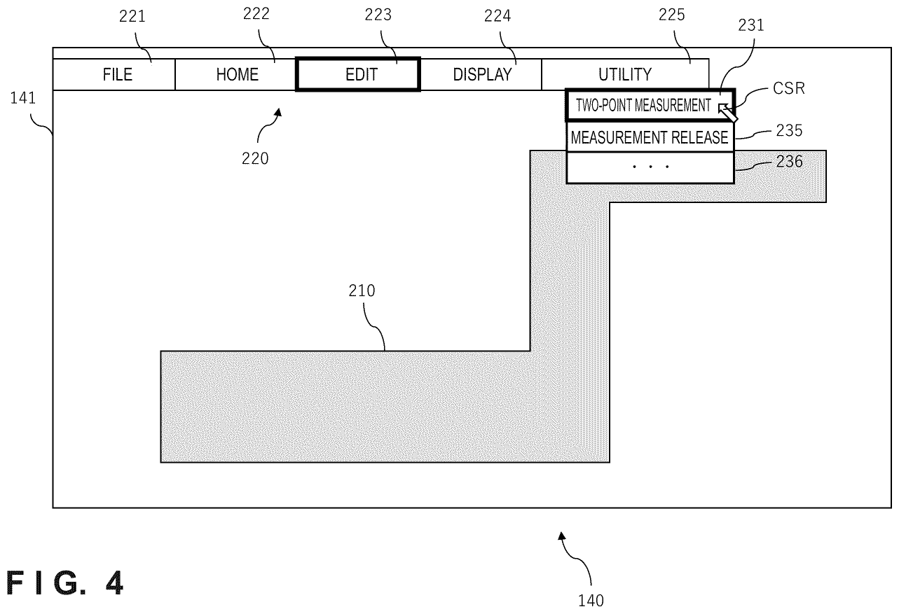

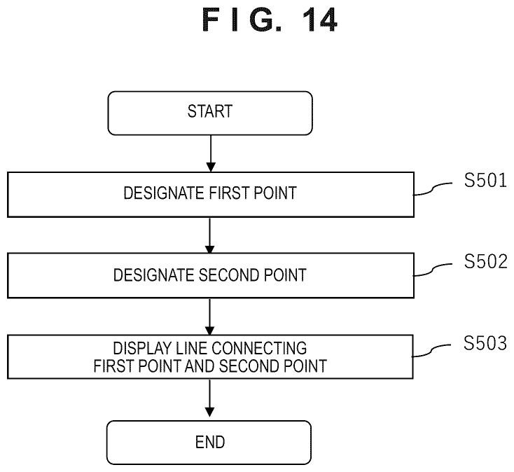

In step S403, the comprehensive control unit 114 determines whether a two-point measurement instruction for measuring an electric characteristic value between two points on the wiring path 210 is issued by the user operating the utility menu button 225 as exemplified in FIGS. 3 and 4. For example, if the user presses the utility menu button 225 in the state exemplified in FIG. 3, the display control unit 113 displays, on the display screen 141, the utility menu including a plurality of utility tools (231, 235, and 236) as exemplified in FIG. 4 under the control of the comprehensive control unit 114. Then, if the two-point measurement tool 231 is selected by the user, the designation unit 111 executes step S404 (measurement path setting) under the control of the comprehensive control unit 114. Details of step S404 will be described later with reference to FIG. 14. The designation unit 111 can designate the first point P1 and the second point P2 in response to a user instruction in a period during which an edit command for editing the layout design is not executed. Alternatively, the designation unit 111 can designate the first point P1 and the second point P2 in response to a user instruction in a period during which an edit command for editing the layout design is executed. Alternatively, the designation unit 111 can designate the first point P1 and the second point P2 in response to a user instruction in a period during which an edit command for editing the layout design is not executed, and in a period during which an edit command for editing the layout design is executed.

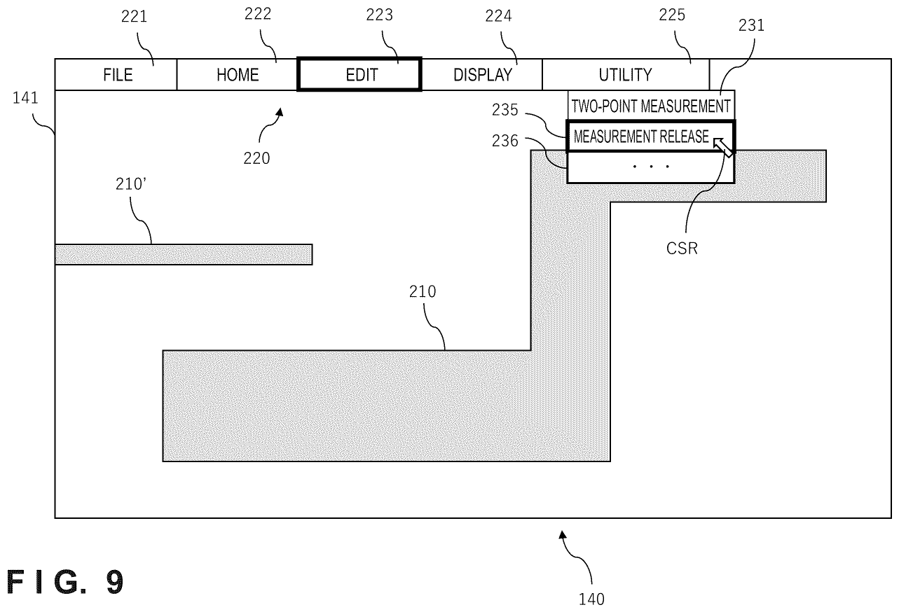

If the two-point measurement tool 231 is not selected in step S403, the comprehensive control unit 114 can execute step S405. In step S405, the comprehensive control unit 114 determines whether the measurement release tool 235 is pressed as exemplified in FIG. 9. If the measurement release tool 235 is pressed, in step S406, the designation unit 111 releases one or a plurality of measurement path designations in accordance with a user operation under the control of the comprehensive control unit 114. That is, the first point P1 and the second point P2 designated by the designation unit 111 can be released by a user instruction. In other words, the first point P1 and the second point P2 designated by the designation unit 111 can be maintained until they are released by a user instruction. If the measurement release tool 235 is not pressed in step S405, or after step S406 is executed, the process returns to step S401.

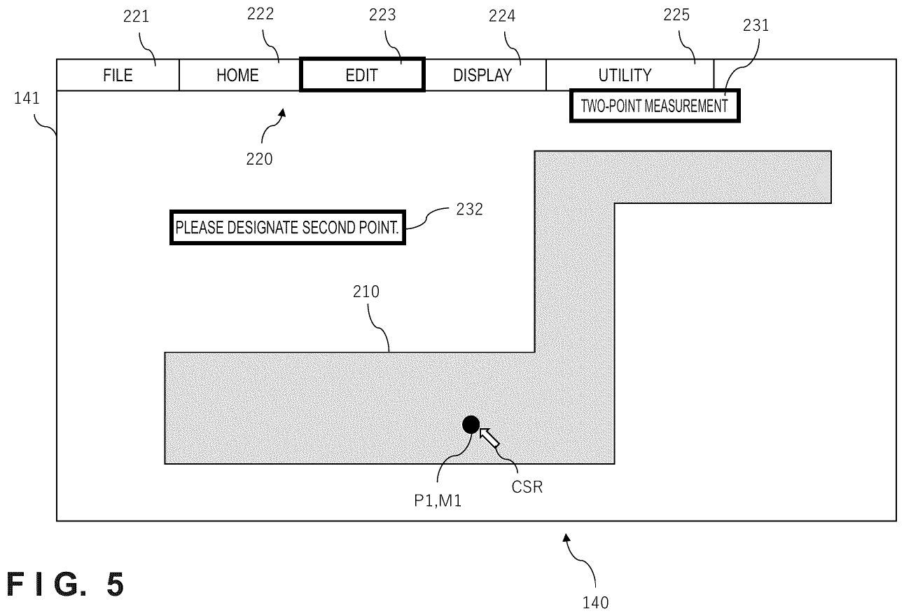

Details of step S404 (measurement path setting) will be described below with reference to FIG. 14. When the two-point measurement tool 231 is selected by the user as exemplified in FIG. 4, in step S501, under the control of the comprehensive control unit 114, the designation unit 111 displays, on the display screen 141, a message 232 for prompting the user to designate the first point P1 as exemplified in FIG. 5, thereby allowing the user to designate the first point P1. In the example shown in FIG. 5, the first point P1 is designated at a position on the wiring path 210. In accordance with the designation of the first point P1, the display control unit 113 can display the first mark M1 indicating the first point P1 so as to overlap the wiring path 210.

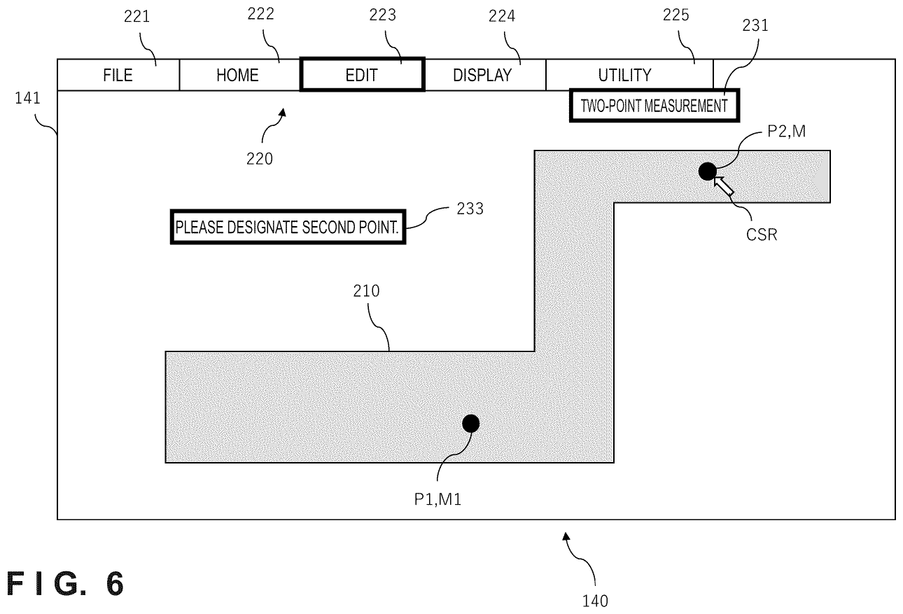

After the user designates the first point P1, in step S502, under the control of the comprehensive control unit 114, the designation unit 111 displays, on the display screen 141, a message 233 for prompting the user to designate the second point P2 as exemplified in FIG. 6, thereby allowing the user to designate the second point P2. The second point P2 is designated at a position on the wiring path 210 where the first point P1 is designated. In accordance with the designation of the second point P2, the display control unit 113 can display the second mark M2 indicating the second point P2 so as to overlap the wiring path 210. Then, in step S503, the display control unit 113 can display the line CL connecting the first mark M1 and the second mark M2 on the display screen 141. By designating the first point P1 and the second point P2 on one continuous wiring path 210, the measurement path for measuring the electric characteristic value is set. Here, by executing step S404 a plurality of times, the designation unit 111 can designate a plurality of measurement paths (two-point pairs). Each measurement path is designated by a two-point pair including the first point P1 and the second point P2.

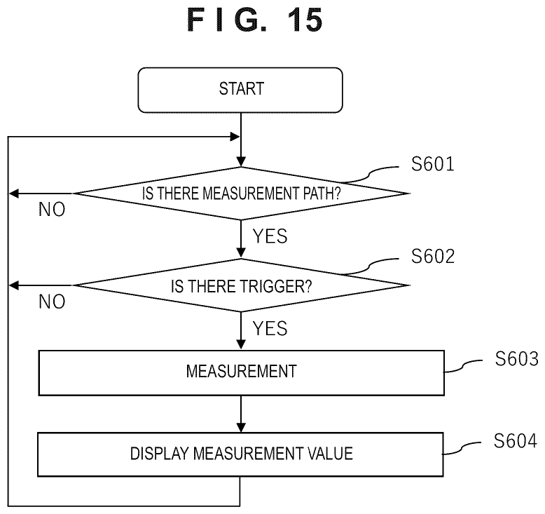

The operation shown in FIG. 15 is executed in parallel with the process shown in FIGS. 13 and 14. In step S601, the comprehensive control unit 114 determines whether there is the measurement path (two-point pair) set in step S404 (measurement path setting). If there is the set measurement path (two-point pair), the comprehensive control unit 114 advances to step S602. In step S602, the comprehensive control unit 114 determines whether there is a trigger for measuring the electric characteristic value of the set measurement path (two-point pair). If there is a trigger, the comprehensive control unit 114 advances to step S603.

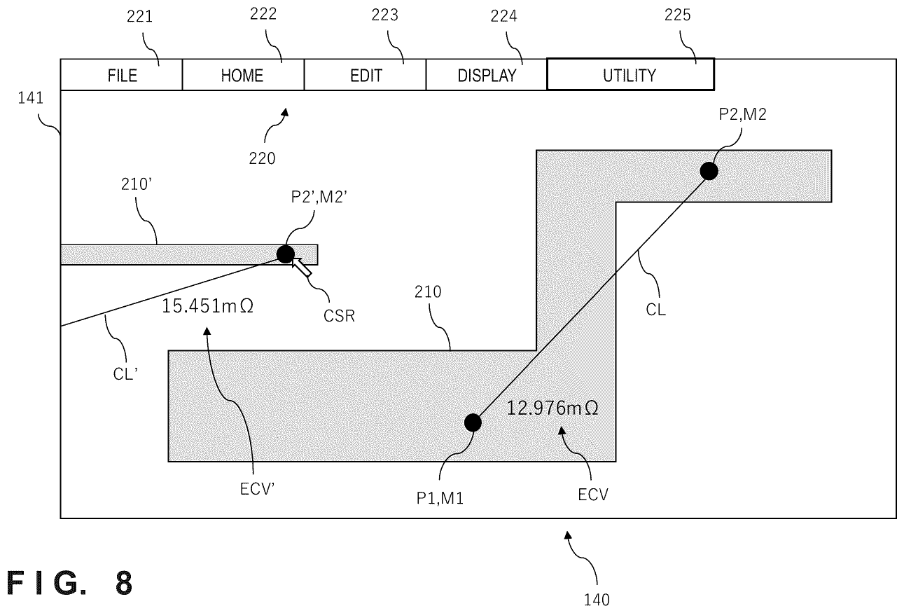

In step S603, the calculation unit 112 calculates the electric characteristic value ECV between the first point P1 and the second point P2 for each measurement path. In step S604, the display control unit 113 displays, on the display screen 141, the electric characteristic value ECV calculated by the calculation unit 112. Each of FIGS. 2, 7, 8, 11, and 12 shows a display example of the electric characteristic value ECV. Among these, FIG. 8 shows an example in which two measurement paths are set. One measurement path is designated by the first point P1 and the second point P2, and the first mark M1 corresponding to the first point P1, the mark M2 corresponding to the second point P2, the line CL connecting the first mark M1 and the second mark M2, and the electric characteristic value ECV are displayed on the display screen 141. The other measurement path is designated by the first point (not shown), which does not fit on the display screen 141, and a second point P2′, and the second mark M2′ corresponding to the second point P2′, a line CL′ connecting the first mark and the second mark M2′, and an electric characteristic value ECV′ are displayed on the display screen 141.

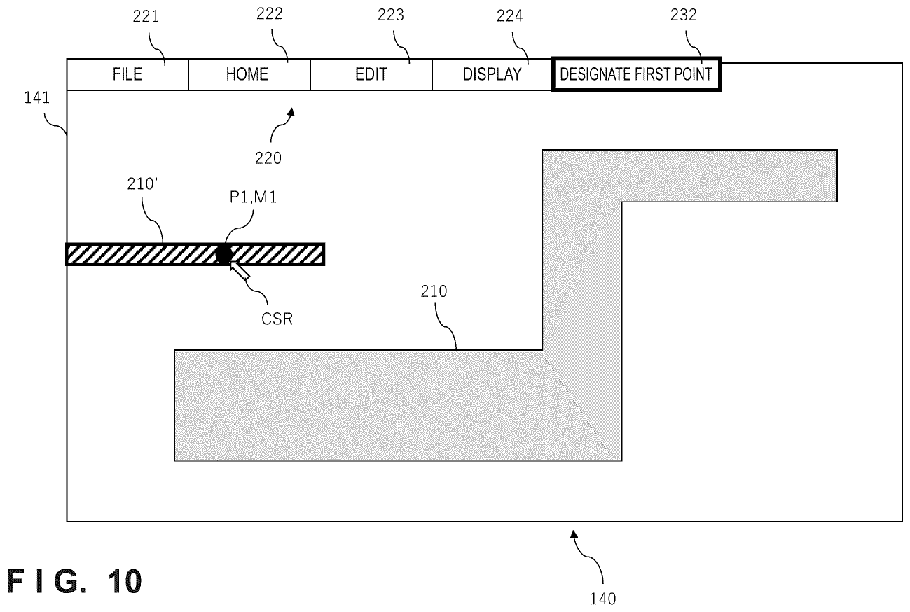

As exemplified in FIG. 10, in accordance with the designation unit 111 designating the first point P1 on a wiring path 210′, the display control unit 113 may highlight the wiring path 210′ on the display screen 141. This can prevent an operational error when the user designates the second point P2 on the wiring path 210′ where the first point P1 is designated, thereby making the work more efficient.

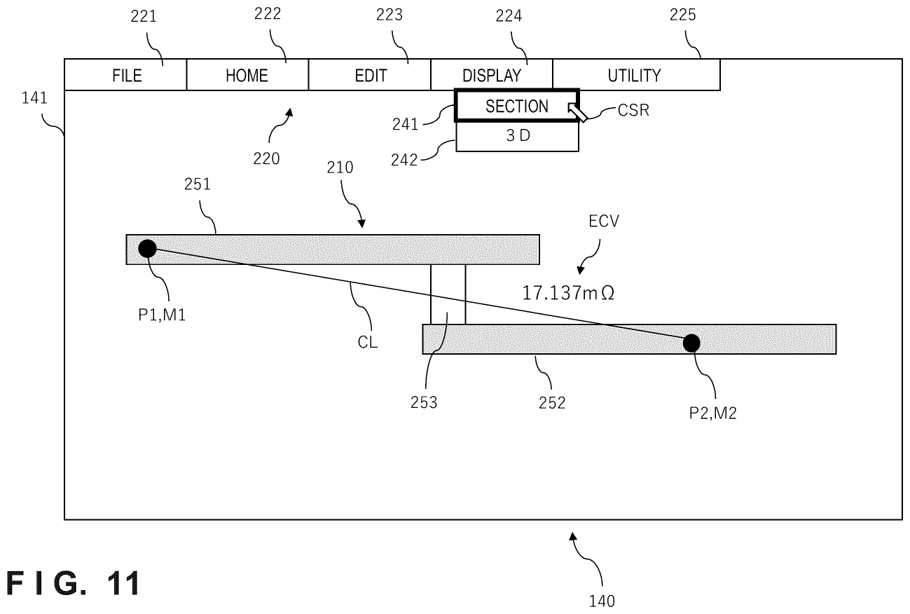

FIG. 11 schematically shows a state in which the display menu button 224 is pressed and a section display button 241 is pressed. When the section display button 241 is pressed and a section display mode is selected, the display control unit 113 generates an image showing the section of the layout of the electronic circuit design being edited, and displays it on the display screen 141. The wiring path 210 can include a terminal (not shown), conductive patterns 251 and 252 in wiring layers, and a via 253. The designation unit 111 can be configured to be capable of designating the first point P1 and the second point P2 on any one of the terminal (not shown), the conductive patterns 251, 252, and the via 253.

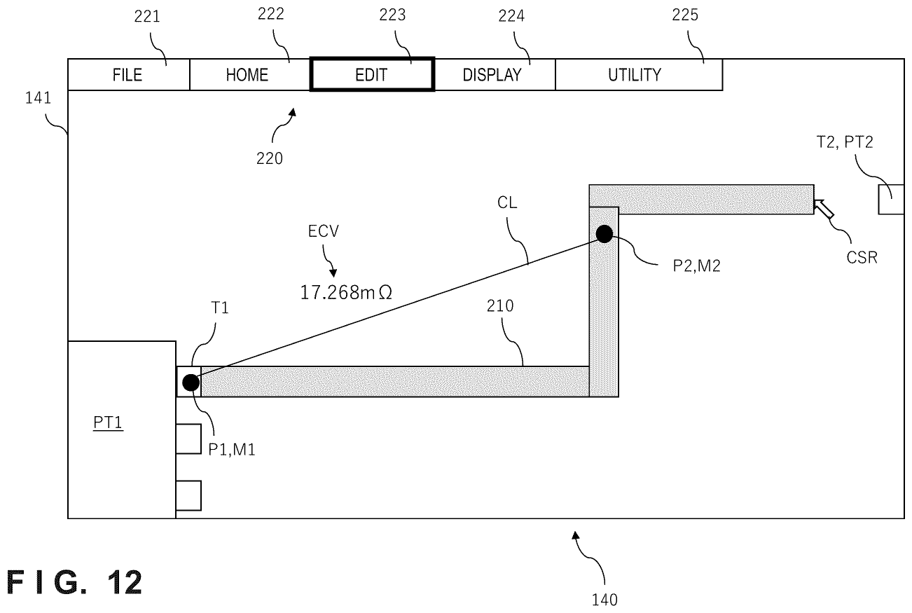

FIG. 12 shows another example of the display image of the display screen 141. In the example shown in FIG. 12, the layout of the electronic circuit design being edited is in a state in which two parts PT1 and PT2 (terminals T1 and T2 thereof) to be electrically connected via the wiring path 210 are not yet electrically connected. Even in the state in which the two parts PT1 and PT2 are not yet electrically connected, if the first point P1 and the second point P2, which are on the wiring path 210 being edited for electrically connecting the two parts PT1 and PT2, are electrically connected, the calculation unit 112 can calculate the electric characteristic value ECV between the first point P1 and the second point P2, and the display control unit 113 can display the electric characteristic value ECV on the display screen 141.

The invention is not limited to the foregoing embodiments, and various variations/changes are possible within the spirit of the invention.

1. A design support apparatus that supports layout design of an electronic circuit, comprising:
a designation unit configured to designate a first point and a second point on a wiring path displayed on a display screen in response to an instruction from a user;
a calculation unit configured to calculate an electric characteristic value between the first point and the second point on the wiring path; and
a display control unit configured to display, on the display screen, the electric characteristic value calculated by the calculation unit.

2. The design support apparatus according to claim 1, wherein
the display control unit displays, on the display screen, a first mark indicating the first point and a second mark indicating the second point so as to overlap the wiring path.

3. The design support apparatus according to claim 2, wherein
the display control unit displays a line connecting the first mark and the second mark on the display screen.

4. The design support apparatus according to claim 1, wherein
the calculation unit re-calculates the electric characteristic value in response to a trigger, and
in accordance with the re-calculation, the display control unit controls display of the display screen so as to update the electric characteristic value displayed on the display screen.

5. The design support apparatus according to claim 4, wherein
the trigger includes an edit operation of the wiring path.

6. The design support apparatus according to claim 4, wherein
the trigger is periodically given.

7. The design support apparatus according to claim 4, wherein
the trigger is given by a user.

8. The design support apparatus according to claim 2, wherein
the display control unit controls display of the display screen so as to delete the first mark and the second mark, which are displayed on the display screen, in accordance with an instruction from a user.

9. The design support apparatus according to claim 1, wherein
the first point and the second point designated by the designation unit are released by an instruction from a user.

10. The design support apparatus according to claim 1, wherein
the first point and the second point designated by the designation unit are maintained until being released by an instruction from a user,
the calculation unit re-calculates the electric characteristic value in response to a trigger, and the display control unit controls, in accordance with the re-calculation, display of the display screen so as to update the electric characteristic value displayed on the display screen, and
the trigger includes an edit operation of the wiring path on which the first point and the second point are designated by the designation unit.

11. The design support apparatus according to claim 1, wherein
the designation unit designates a plurality of two-point pairs each including the first point and the second point.

12. The design support apparatus according to claim 1, wherein
the designation unit designates the first point and the second point in response to an instruction from a user in a period during which an edit command for editing the layout design is not executed, and a period during which the edit command is executed.

13. The design support apparatus according to claim 1, wherein
in accordance with the designation unit designating the first point on the wiring path, the display control unit highlights the wiring path on the display screen.

14. The design support apparatus according to claim 1, wherein
the wiring path includes a terminal, a conductive pattern in a wiring layer, and a via, and
the designation unit can designate the first point and the second point on any one of the terminal, the conductive pattern, and the via.

15. The design support apparatus according to claim 1, wherein
in a case where two parts to be electrically connected via the wiring path are not yet electrically connected but the first point and the second point are electrically connected, the calculation unit calculates the electric characteristic value between the first point and the second point.

16. The design support apparatus according to claim 1, wherein
the electric characteristic value includes a resistance value.

17. A design support method for supporting layout design of an electronic circuit, comprising:
a designation step of designating a first point and a second point on a wiring path displayed on a display screen in response to an instruction from a user;
a calculation step of calculating an electric characteristic value between the first point and the second point on the wiring path; and
a display control step of displaying, on the display screen, the electric characteristic value calculated in the calculation step.

18. (canceled)

19. A non-transitory computer readable medium storing a computer program for causing a computer to operate as a design support apparatus defined in claim 1.

20. The design support apparatus according to claim 5, wherein
the trigger is periodically given.

21. The method according to claim 17, wherein
the first point and the second point designated in the designation step are maintained until being released by an instruction from a user,
the calculation step includes re-calculating the electric characteristic value in response to a trigger, and the display control step includes controlling, in accordance with the re-calculation, display of the display screen so as to update the electric characteristic value displayed on the display screen, and
the trigger includes an edit operation of the wiring path on which the first point and the second point are designated in the designation step.
